(19) United States
(12) Patent Application Publication
(10) Pub. No.: US 2025/0258888 A1
(43) Pub. Date: Aug. 14, 2025

(54) BINARY-UNARY COMPUTING USING SELF-SIMILAR SUB-FUNCTIONS

(71) Applicant: Regents of the University of Minnesota, Minneapolis, MN (US)

(72) Inventors: Alireza Khataei, Minneapolis, MN (US); Kiarash Bazargan, Plymouth, MN (US)

(21) Appl. No.: 19/048,393

(22) Filed: Feb. 7, 2025

Related U.S. Application Data
(60) Provisional application No. 63/551,379, filed on Feb. 8, 2024.

(51) Int. Cl. G06F 17/11; H03K 19/21

(52) U.S. Cl. CPC G06F 17/11; H03K 19/21

(57) ABSTRACT

A digital system that implement functions, including non-linear functions, by breaking the functions into sub-functions such that all the sub-functions have an equal input range. The processing circuitry further uses a number of linear transformations to check if one of the sub-functions can be derived from another sub-function, e.g. to determine self-similarities between the sub-functions. The result is a set of unique, primary sub-functions and a set of secondary sub-functions that may be derived from the primary sub-functions. The processing circuitry of this disclosure is configured to execute instructions that measure pair-wise similarities between sub-functions to find the minimum set of primary sub-functions, from which all the other sub-functions can be derived using a set of bit transformations.

This application claims the benefit of U.S. Provisional Patent Application No. 63/551,379, filed 8 Feb. 2024, the entire contents of which is incorporated herein by reference.

### GOVERNMENT INTEREST

This invention was made with government support under IIP2031325 awarded by the National Science Foundation. The government has certain rights in the invention.

### TECHNICAL FIELD

The disclosure relates computing systems that operate using binary and unary computing.

### BACKGROUND

Digital systems execute functions to perform the tasks for which the digital systems are designed. The digital systems may be implemented as a hardware device configured to perform the desired tasks, such as a Field Programmable Gate Array (FPGA) or similar computing device. Some examples of functions that the computing device may execute may include sine, cosh, tanh, exponential, gamma, and any number of other linear or non-linear functions. Some considerations when generating the hardware IP blocks that implement functions may include power consumption, latency, amount of area on the device used to implement the function, desired accuracy and resolution, hardware cost and other similar considerations. The digital systems may implement the functions using, for example, binary representation, unary representation, a hybrid binary-unary representation, as well as other computing techniques.

### SUMMARY

In general, the disclosure describes digital systems and methods to generate hardware computing devices using hybrid binary-unary (HBU). HBU breaks an input value into upper binary bits, and lower binary bits. The lower binary bits are transformed to unary encoding such as thermometer codes. As a result, a function is broken into sub-functions indexed with the upper binary bits, and the sub-functions with limited input and output ranges are implemented either based on the pure unary (PU) method or a look-up table. The processing circuitry of the digital systems of this disclosure may execute the instructions of a synthesis algorithm to implement functions, including non-linear functions, by breaking the functions into sub-functions such that all the sub-functions have an equal input range, which may also be referred to as a uniform input range. The processing circuitry executing the instructions of the synthesis algorithm further uses a number of linear transformations to check if one of the sub-functions can be derived from another sub-function, e.g. to determine self-similarities between the sub-functions. The result is a set of unique, primary sub-functions and a set of secondary sub-functions that may be derived from the primary sub-functions. The processing circuitry executing the synthesis algorithm of this disclosure is configured to perform analysis that measures pair-wise similarities between sub-functions to find the minimum set of primary sub-functions, from which all the other sub-functions can be derived using a set of bit transformations.

The processing circuitry by executing the synthesis algorithm of this disclosure may, in addition, be configured to divide and transform each of the original functions into a set of sub-functions in such a way that the upper K bits of the output in each sub-function are the same in the binary domain, where K is a predetermined integer. This also divides the input length of the original input function into n sub-regions. Because the upper K bits of each sub-function are fixed, the processing circuitry may separate those K bits and rewrite each sub-function as a truncated sub-function by omitting the upper K bits of each sub-function. To generate the original sub-function using bit-concatenation, the processing circuitry executing the synthesis algorithm may concatenate the removed upper bits to the truncated sub-function. Using such a transformation, the processing circuitry may implement each truncated sub-function in the unary domain or the binary domain through look-up tables at a lower resolution than the original function. Implementing the truncated sub-function in the unary domain allows the processing circuitry to generate the hardware computing device using thermometer encoders and decoders to perform the computations.

Because the processing circuitry executing the synthesis algorithm divided the input length of the function into n sub-regions, the processing circuitry may generate in hardware n fully unary cores or look-up tables to implement each sub-function. The hardware computing device would compute n different outputs in parallel, where at least one of the outputs contributes to the final binary output. The hardware computing device then concatenates the removed upper bits to multiplex the correct output.

In one example, the disclosure describes a method comprising: receiving, by the processing circuitry of a computing system executing the synthesis algorithm, an input function; dividing the input function into a set of sub-functions, each of the set of sub-functions comprising a uniform input range; measuring pair-wise similarities between the sub-functions in the set of sub-functions; and determining a set of primary sub-functions and a set of secondary sub-functions, of the set of sub-functions based on the pair-wise similarities, wherein: each sub-functions in the secondary set of sub-functions is derivable from the primary set of sub-functions using a set of bit transformations.

In another example, the disclosure describes a method comprising: receiving, by processing circuitry of a computing system executing the synthesis algorithm, an input function; dividing and transforming, by the processing circuitry, the input function into a set of sub-functions, such that predetermined number of upper bits for each sub-function of the set of sub-functions are the same in the binary domain; separating, by the processing circuitry, respective upper bits for each sub-function from the respective sub-function resulting in a set of truncated sub-functions; implementing each truncated sub-function as a pure unary, PU, core; generating, by the computing system, hardware that concatenates the separated respective upper bits to each respective truncated sub-function for a binary output from the generated hardware.

In another example, the disclosure describes a non-transitory computer-readable storage medium comprising instructions that, when executed, cause processing circuitry of a computing device to: receive an input function; divide the input function into a set of sub-functions, each of the set of sub-functions comprising a uniform input range; measure pair-wise similarities between the sub-functions in the set of sub-functions; determine a set of primary sub-functions and a set of secondary sub-functions, of the set of sub-functions based on the pair-wise similarities, wherein: each sub-functions in the secondary set of sub-functions is derivable from the primary set of sub-functions using a set of bit transformations.

In another example, the disclosure a non-transitory computer-readable storage medium comprising instructions that, when executed, cause processing circuitry of a computing device to: receive an input function; divide and transform the input function into a set of sub-functions, such that predetermined number of upper bits for each sub-function of the set of sub-functions are the same in the binary domain; separate respective upper bits for each sub-function from the respective sub-function resulting in a set of truncated sub-functions; implement each truncated sub-function as a pure unary, PU, core; generate hardware that concatenates the separated respective upper bits to each respective truncated sub-function for a binary output from the generated hardware.

In another example, the disclosure describes a circuit comprising: circuitry configured to receive a binary input; a single binary-to-unary encoder configured to convert the received binary input to unary input; one or more pure unary, PU, cores, configured to receive the converted unary input wherein each PU core is configured to implement a primary sub-function; one or more unary-to-binary decoders, wherein each respective unary-to-binary decoders is configured to receive a respective output from a respective PU core of the one or more PU cores; a transformer, wherein the transformer comprises circuitry configured to derive secondary sub-functions from the primary sub-functions; circuitry configured to output results computed by the primary sub-functions and the secondary sub-functions.

The details of one or more examples of the disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 is a block diagram illustrating an example hardware IP block synthesis system configured to generate a hardware IP block that executes one or more functions to be used in a computing device.

FIG. 2 is a block diagram illustrating an example hardware architecture of a function generated by the function similarity and transformation technique of this disclosure.

FIGS. 3A, 3B and 3C are graphs illustrating an example of breaking an input function into sub-functions according to the function similarity and transformation technique of this disclosure.

FIGS. 4A, 4B, 4C, 4D and 4E are example similarity matrices and similarity vectors for processing the example input function, F(x), described by FIGS. 3A-3C.

FIG. 5 is a block diagram illustrating an example hardware architecture of a function generated by the function division and concatenation technique of this disclosure.

FIGS. 6A-6F are graphs illustrating an example of breaking an input function into sub-functions according to the function division and concatenation techniques of this disclosure.

FIG. 7 is a flow chart illustrating an example operation based on the function similarity and transformation techniques of this disclosure.

FIG. 8 is a flow chart illustrating an example operation based on the function division and concatenation techniques of this disclosure.

### DETAILED DESCRIPTION

A digital system implements functions, including non-linear functions, in some examples, by dividing (e.g., breaking) the functions into sub-functions such that all the sub-functions have an equal input range. The processing circuitry executing the synthesis algorithm further uses a number of linear transformations to check if one of the sub-functions can be derived from another sub-function, e.g. to determine self-similarities between the sub-functions. The result is a set of unique, primary sub-functions and a set of secondary sub-functions that may be derived from the primary sub-functions. The processing circuitry executing the synthesis algorithm of this disclosure is configured to perform analysis that measures pair-wise similarities between sub-functions to find the minimum set of primary sub-functions, from which all the other sub-functions can be derived using a set of bit transformations. The result is fewer primary sub-functions that would be implemented by pure unary cores or look-up tables.

In other examples, the digital system of this disclosure may independently, or in addition, be configured to divide and transform each of the original functions into a set of sub-functions in such a way that the upper K bits of the output in each sub-function are the same in the binary domain. Because the upper K bits of each sub-function are fixed, the processing circuitry executing the synthesis algorithm may separate those K bits and rewrite each sub-function as a truncated sub-function by omitting the upper K bits of each sub-function. To generate the original sub-function using bit-concatenation, the processing circuitry may concatenate the removed upper bits to the truncated sub-function for the binary output.

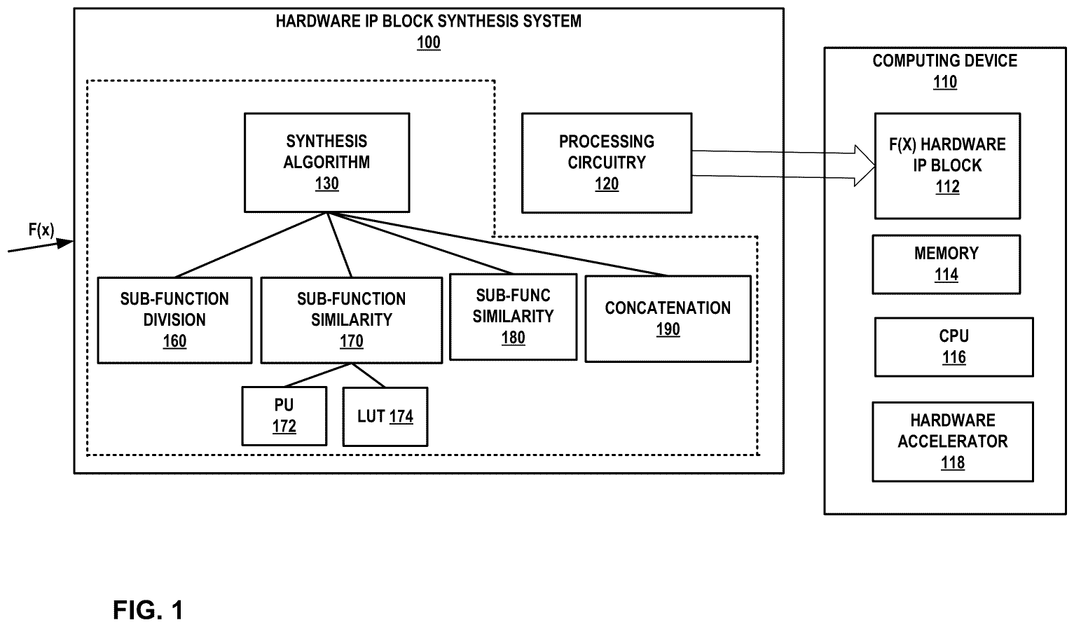

FIG. 1 is a block diagram illustrating an example hardware IP block synthesis system configured to generate a hardware IP block that executes one or more functions to be used in a computing device. In the example of FIG. 1, hardware IP block synthesis system 100 includes processing circuitry 120 that executes the synthesis algorithm 150 residing in its memory 125, procedures for sub-function division 160, sub-function implementation 170, pure unary PU implementation 172, look-up table LUT implementation 174, sub-function similarity 180, and concatenation 190. Hardware IP block synthesis system 100 receives as an input a function, F(x), and generates hardware IP block 112 to implement F(x) to be used in the target computing device 110 along with other compute units such as central processing unit (CPU) 116, other hardware accelerators such as 118, all accessing memory 114. Processing circuitry 120 may generate the hardware IP block 112 in the form of hardware description languages such as RTL, Verilog, VHDL, and HLS.

Processing circuitry 120 executing synthesis algorithm 150 may process input function F(x) by either of two independent techniques, sub-function similarity 180 or by concatenation 190. In some examples, processing circuitry 120 may combine both sub-function similarity 180 and concatenation 190 to process function F(x). F(x) may be any linear or non-linear function.

Processing circuitry 120 executing synthesis algorithm 150 may process sub-functions of the input function F(x) by either of two independent techniques, pure unary PU 172, or look-up table LUT 174. The look-up table procedure generates constant value look-up tables that map the input variable x to the F(x) value at that input.

Instructions stored at sub-function similarity and transform procedure 180, when executed by processing circuitry 120 may receive F(x), and break function F(x) into sub-functions and separate the initial biases for each sub-function. In some examples, the instructions may introduce controlled levels of approximation. By breaking the function with uniform input ranges, processing circuitry 120 may only generate one encoder for the hardware to convert the b lower bits from binary to unary. Processing circuitry 120 may then measure pair-wise similarities between sub-functions, in some examples based on a target maximum error, to find a minimum set of unique, primary sub-functions, from which all the other sub-functions can be derived using a set of bit transformations. This self-similarity comparison may reduce the number of sub-functions that would be implemented using PU cores or look-up tables.

In other examples, processing circuitry 120 executing the synthesis algorithm 150 may process F(x) based on instructions stored at function concatenation 190. Processing circuitry 120 may receive F(x), then divide, and transform F(x) into a set of sub-functions in such a way that the upper K bits of the output in each sub-function are the same in the binary domain. Because the upper Kbits of each sub-function are fixed, processing circuitry 120 may separate the respective upper K bits from each sub-function.

Using such a transformation, each truncated sub-function may be implemented in the unary domain at a lower resolution than the original function F(x). Therefore, processing circuitry 120 may utilize low-cost thermometer encoders and decoders using the PU 172 technique to perform the computations. For the output, processing circuitry 120 may use the concatenate 190 technique to concatenate each respective upper K bits to each respective truncated sub-function. For instance, processing circuitry 120 may include second circuitry configured to concatenate the results computed by the primary sub-functions and the secondary sub-functions with upper bits of the input. The bit-concatenation of the respective upper K bits to each respective sub-function creates each output sub-function.

For sub-function division 160, processing circuitry 120 divides the input length of received function F(x) into n sub-regions. Therefore, processing circuitry 120 may use n fully unary cores or look-up tables to implement each truncated sub-function. The generated hardware, e.g., hardware IP block 112, may compute the n different outputs in parallel. At least one of the outputs contributes to the final binary output. To concatenate the respective upper K bits, the generated hardware may multiplex the respective removed upper bits of the respective truncated sub-function for the binary output from the generated hardware.

In some examples, processing circuitry 120 may use sub-function division 160, and combine sub-function similarity 180 and concatenation 190 to generate hardware IP block 112. For example, processing circuitry 120 may process F(x) using sub-function division 160 and concatenate 190 to divide and transform F(x) into a set of truncated sub-functions. Processing circuitry 120 may then process the truncated sub-functions using the self-similarity techniques of 180 to reduce the number of sub-functions that would be implemented with PU cores or look-up tables. Finally, processing circuitry 120 may generate hardware that concatenates the respective removed upper bits for each respective truncated sub-function.

Examples of processing circuitry 120 may include any one or more of a microcontroller (MCU), e.g. a computer on a single integrated circuit containing a processor core, memory, and programmable input/output peripherals, a microprocessor (μP), e.g. a central processing unit (CPU) on a single integrated circuit (IC), a controller, a digital signal processor (DSP), an application specific integrated circuit (ASIC), a field-programmable gate array (FPGA), a system on chip (SoC) or equivalent discrete or integrated logic circuitry. A processor may be integrated circuitry, i.e., integrated processing circuitry, and that the integrated processing circuitry may be realized as fixed hardware processing circuitry, programmable processing circuitry and/or a combination of both fixed and programmable processing circuitry. Accordingly, the terms “processing circuitry,” “processor” or “controller,” as used herein, may refer to any one or more of the foregoing structures or any other structure operable to perform techniques described herein.

Examples of memory 125 may include any type of computer-readable storage media. Some examples may include random access memory (RAM), read only memory (ROM), programmable read only memory (PROM), erasable programmable read only memory (EPROM), one-time programable (OTP) memory, electronically erasable programmable read only memory (EEPROM), flash memory, or another type of volatile or non-volatile memory device. In some examples the computer readable storage media may store instructions that cause the processing circuitry to execute the functions described herein. In some examples, the computer readable storage media may store data, such as configuration information, temporary values and other types of data used to perform the functions of this disclosure.

Processing circuitry 120 executing synthesis algorithm 150 may process received function F(x) so that F(x) may be implemented in hardware, e.g., hardware IP block 112, as part of computing device 110. As noted above, computing device 110 may be any of several computing devices, including a field programmable gate array (FPGA) or similar computing device. When executing programming instructions in sub-function similarity procedure 180, processing circuitry 120 following instructions in sub-function division 160 may uniformly break a function F(x) into n=2^{b} sub-functions and separate each respective initial bias for each sub-function. For a w-bit function, the input range of all sub-functions is u=w−b bits. The set of sub-functions for F(x) includes:

$$\begin{matrix}{f}_{1} ( x ) = {b}_{1} + {g}_{1} ( x ) & x ∈ [ 0 , {2}^{u} ) \\ To & \\ {f}_{n} ( x ) = {b}_{n} + {g}_{n} ( x ) & x ∈ [ ( n - 1 ) \times {2}^{u} , n \times {2}^{u} )\end{matrix}$$

By uniformly breaking the function, only one encoder is needed to convert the b lower bits from binary to unary. Then as noted above, processing circuitry 120 finds self-similarities between functions to find primary sub-functions from which the secondary sub-functions may be derived by bit transformations. For instance, if gᵢ(x) is similar to the inverse of gⱼ(x), then processing circuitry 120 can implement gⱼ(x) and use NOT gates to derive gᵢ(x) from it.

The approximation error of deriving gᵢ(x) from gⱼ(x) through a transformation Tᵢ is defined as:

$$Err ( {g}_{i} , T , {g}_{j} ) = max \{ \vert Fixed ( {b}_{i} + {bm}_{i} + {T}_{i} \{ {g}_{j} ( x ) \} ) - Float ( {b}_{i} + {g}_{i} ( x ) ) \vert \}$$

where Fixed(x) and Float(x) denote the fixed-point and floating-point values of the unsigned integer x, respectively. T is a bit-wise transformation, that can include an inversion, right shift, and left shift, and bmᵢ is a constant that modifies the vertical position of T{gⱼ(x)} to reduce the approximation error, and it can be obtained by

$${bm}_{i} = ⌊ \frac{1}{{2}^{u}} {\sum }_{x} ( {g}_{i} ( x ) - {T}_{i} \{ {g}_{j} ( x ) \} ) ⌉$$

where └ ┐ denotes the rounding to the nearest integer function. The constant bmi tries to “center” the transformed sub-function around the center of gravity of the target sub-function to reduce the amount of error in deriving the function. This constant bmᵢ should not get an arbitrary value and there are constraints on bmᵢ, as described.

$$0 \leq {b}_{i} + {bm}_{i} + {T}_{i} \{ {g}_{j} ( x ) \} < {2}^{w}$$

Given a target approximation error TargetErr, processing circuitry 120 may derive a secondary sub-function gᵢ(x) from a primary sub-function gⱼ(x) if

∃T,Err(gᵢ,Tᵢ,gⱼ)≤TargetErr

The similarity matrix of this disclosure is defined as a n×n binary matrix, in which an entry in the matrix smᵢⱼ is 1 if and only if gᵢ(x) is derivable from gⱼ(x), subject to the constraint described above. The similarity matrix, SM, may be described by:

$$\begin{matrix}SM = [ {sm}_{ij} ] n \times n ; & {sm}_{ij} ∈ \{ 0 , 1 \} , \\ {sm}_{ij} = 1 ⇔ ∃ T , & Err ( {g}_{i} , {T}_{i} , {g}_{j} ) \leq Target Err\end{matrix}$$

Processing circuitry 120 may define the similarity vector of this disclosure as a vector of n elements, and equal to the summation of the rows of the similarity matrix SM, which can be represented as

$$SV = {[ {sv}_{j} ]}_{1 xn} ; {sv}_{j} = {\sum }_{i} {sm}_{ij}$$

Processing circuitry 120, following instructions in sub-function similarity 180 determines the set of primary sub-functions with the set of secondary sub-functions derived from the primary sub-functions using the bit transformation, e.g., Ti above. If gi(x) is derivable from gj(x), then

$$\begin{matrix}∃ Ti , & Err ( {g}_{i} , {T}_{i} , {g}_{j} ) \leq Target Err \\ & ⇒ ( {b}_{i} + {g}_{i} ( x ) ) ≃ ( {b}_{i} + {bm}_{i} ) + {T}_{i} \{ {g}_{j} ( x ) \} \\ & ⇒ {f}_{i} ( x ) ≃ \hat{{b}_{i}} + T \{ {g}_{j} ( x ) \}\end{matrix}$$

If there exist multiple transformations that can derive gi(x) from gj(f), processing circuitry 120 chooses the one that minimizes the approximation error.

Tᵢ=argminErr(gᵢ,Tᵢ,gⱼ)

Therefore, processing circuitry 120 may compute fᵢ(x)≅\hat{b}ᵢ+Tᵢ{gⱼ(x)} instead of fᵢ(x)=bᵢ+gᵢ(x). That is, system 100 may implement fᵢ(x) by storing the pre-calculated bias \hat{b}ᵢ=bᵢ+bmᵢ in the binary look-up table and transforming the sub-function gⱼ(x), implemented using the PU method.

To find the minimum set of unique sub-functions, processing circuitry 120 may first compute the similarity matrix, SM, and similarity vector, SV, as described above. The index of the maximum element in the similarity vector (i.e. idx=arg minᵢ SV [i]) determines the first unique function.

Processing circuitry 120 then traverses through the idxth column of the similarity matrix to determine which sub-functions can be derived from gidx(x). Next, processing circuitry 120 updates the similarity matrix, SM, by zeroing the idxth row and column as well as all the rows and columns corresponding to the functions that are derivable from gidx(x). Again, processing circuitry 120 computes the similarity vector and finds the next unique sub-function. Processing circuitry 120 may continue this process until all the entries of the similarity matrix get set to zero. To represent the final set of unique sub-functions in this algorithm, processing circuitry 120 defines two vectors Unique and Transformation such that if Unique[i]=j and Transformation[i]=Ti, then fi(x) is derived from fj(x) through transformation Ti. Vectors Sub and Bias are also defined to store each output values and bias for each sub-function. This process may also be described by the below pseudo-code. In other words, the below listing of pseudo-code may include one possible example of the instructions executed by processing circuitry 120 to implement sub-function similarity 180. In this disclosure “Unique” refers to unique, primary sub-functions.

Function Similarity and Transformation Algorithm

| | |
|---|---|
| 1 | Parameters: TargetErr,w, u, b |
| 2 | Input: F = {y = f(x)\| x, y ∈ Z and x, y ∈ [0, 2^{w})} |
| 3 | Outputs: Sub, Bias, Unique, Transformer |
| 4 | # Uniformly breaking the function into sub-functions |
| 5 | for i = 1 to 2^{b} do |
| 6 | Sub[i] ← F[(i − 1) × 2^{u} : i × 2^{u}] |
| 7 | Bias[i] ← min(Sub[i]) |
| 8 | Sub[i] ← Sub[i] − Bias[i] |
| 9 | end |
| 10 | # Making pair-wise comparisons of the sub-functions |
| 11 | for i = 1 to 2^{b} do |
| 12 | for j = 1 to 2^{b} do |
| 13 | if ∃T, Err(Sub[i], T, Sub[j]) ≤ TargetErr |
| | then |
| 14 | SM[i][j] ← 1 |
| 15 | else |
| 16 | SM[i][j] ← 0 |
| 17 | end |
| 18 | end |
| 19 | end |
| 20 | # Finding the minimum set of unique sub-functions |
| 21 | while ΣᵢΣⱼ SM[i][j] ! = 0 |
| 22 | SV ← Σᵢ SM[i][:] |
| 23 | idx ← argmaxᵢ SV[i] |
| 24 | for i = 1 to 2^{b} do |
| 25 | if i ! = idx and SM[idx][i] == 1 then |
| 26 | Similarity[i] ← idx |
| 27 | T ← argminT Err(Sub[i], T, Sub[idx]) |
| 28 | Transformer[i] ← T |
| 29 | bmi = └ 1/2^{u} Σₓ(fᵢ(x) − T{fᵢ(x)})┐ |
| 30 | Bias[i] ← Bias[i] + bmi |
| 31 | SM[i][:] ← 0 |
| 32 | SM[:][i] ← 0 |
| 33 | end |
| 34 | end |
| 35 | Unique[idx] ← idx |
| 36 | Transformer[idx] ← None |
| 37 | SM[idx][:] ← 0 |
| 38 | SM[:][idx] ← 0 |
| 39 | end |

In other examples, processing circuitry 120 executing the synthesis algorithm 150 may process an arbitrary input function, F(x) by executing instructions stored at sub-function division 160 and function concatenation 190 to divide and transform F(x) to reduce hardware cost and approximation error. The below table lists parameters used for function concatenation 190.

| Parameter | Description |
|---|---|
| IL | Initial division length |
| Lₘᵢₙ | Sub-function minimum input length |
| K | # Upper bits to be fixed in sub-functions |
| TRE | Target rounding error |
| TSE | Target similarity error |

The below listed pseudo code may include one possible example of instructions executed by processing circuitry 120 to implement function concatenation 198:

Function Division and Concatenation

| | |
|---|---|
| 1 | Parameters: IL, Lmin,K,TRE |
| 2 | Input: f (x) |
| 3 | Output: g(x), UB, gBoundaries |
| 4 | xₛ ← 0; |
| 5 | // (6-9) Dividing the input region by 2IL |
| 6 | for i = 1 to 2^{win-IL} do |
| 7 | f Boundaries.push([xₛ , xₛ + 2^{IL} − 1]) |
| 8 | xₛ ← xₛ + 2IL |
| 9 | end |
| 10 | while f Boundaries ≠ NULL do |
| 11 | [xₛ , xₑ ] ← f Boundaries.pop( ) |
| 12 | fsub ← f ( [xₛ , xₑ ]) |
| 13 | // (14-15) Finding min / max of K upper bits |
| 14 | minUB ← └min( f_{sub})/2^{wout -K}┘ |
| 15 | maxUB ← └max ( f_{sub})/2^{wout -K}┘ |
| 16 | if minUB = maxUB then |
| 17 | gBoundaries.push([xₛ , xₑ ]) |
| 18 | \hat{f} ← fsub |
| 19 | else |
| 20 | // (21-29) Computing the lowest RoundingError for the K upper |
| | bits |
| 21 | BestRE ← inf |
| 22 | for i = 0 to 2^{K} − 1 do |
| 23 | ftemp ← (i × 2wout−K) + ( fsub mod 2wout −K) |
| 24 | RE ← RoundingError ( fsub, ftemp ) |
| 25 | if RE < bestRE then |
| 26 | bestRE ← RE |
| 27 | bestUB ←i |
| 28 | end |
| 29 | end |
| 30 | // (31-37) Applying the approximation or dividing the sub-region |
| | by 2 |
| 31 | if bestRE < TRE or Lₘᵢₙ = (xₑ − xₛ) then |
| 32 | gBoundaries.push([xs , xe ]) |
| 33 | \hat{f} ← bestUB × 2^{wout -K} + f_{sub} mod 2^{wout -K} |
| 34 | else |
| 35 | f Boundaries.push([xₛ , (xₑ − 1)/2]) |
| 36 | f Boundaries.push([(xₑ + 1)/2, xₑ ]) |
| 37 | end |
| 38 | end |
| 39 | end |
| 40 | g ← \hat{f} mod 2^{wout -K} |
| 41 | UB ← └\hat{f} /2^{wout -K}┘ |

Input function F(x) may be an arbitrary math function that may have the input and output resolutions wᵢₙ and wₒᵤₜ. In this process, the input and output values of the functions are considered an unsigned integers, although they may originally represent other values. As a result of this algorithm, g(x), UB, and gBoundaries are returned as outputs, where gBoundaries is a list of tuples that determines the input range of each gi (x), and UB is the list of “UBi”s.

In the first loop (lines 6-9), processing circuitry 120 divides the input domain [0, 2wout−1] into IL-bit sub-regions, and stores results in a list called f Boundaries. In fact, f Bouandaries is a list of tuples, each of which corresponds to the input domain of a sub-function that still requires transformation and processing. Once processing circuitry 120 processes and finalizes a sub-region, processing circuitry 120 stores the sub-region in gBouandaries.

In the next loop (lines 10-39), in each iteration, processing circuitry 120 selects an input sub-region from f Bouandaries and removes that sub-region from the f Bouandaries list. Next, processing circuitry 120 checks whether the upper K bits of F(x) in this region are fixed or not. If the upper K bits are fixed, processing circuitry 120 stores this sub-region into gBouandaries and the corresponding output values of F(x) into f(x). If the upper K bits are not fixed, processing circuitry 120 may round the sub-function output to the nearest values whose upper K bits are fixed in this sub-region. Among all the 2K options for the upper bits format, processing circuitry 120 may choose the option which results in the minimum rounding error.

If this minimum rounding error for the sub-region is less than TRE, or the length of the sub-region is equal to Lmin, processing circuitry 120 may store this sub-region into gBouandries and the corresponding rounded values f(x) into f(x). Otherwise, if this minimum rounding error for the sub-region is not less than TRE, processing circuitry 120 may divide this sub-region by 2 and store both sub-regions into f Bouandries. Processing circuitry 120 may calculate the rounding error based on the mean absolute error equation as follows:

$$RoundingError = \frac{1}{m} {\sum }_{x} \vert \frac{{f}_{temp} ( x ) - {f}_{sub} ( x )}{{2}^{{w}_{out}}} \vert$$

At the end of the while loop, gBouandries contains a list of tuples that corresponds to the input domains of sub-functions whose upper K bits are fixed. Therefore, processing circuitry 120 may separate these upper bits from f(x) and store the resulting values as g(x). Processing circuitry 120 may also store the upper bits of each sub-function in a list called UB.

In this manner processing circuitry 120 may transform and divide arbitrary input function F(x) into a set of sub-functions fᵢ (x) whose upper K bits are fixed. In this manner, hardware IP block synthesis system 100 may generate hardware that temporarily eliminates the upper bits, and implement each truncated sub-function (denoted as gᵢ (x)) in the fully unary domain using only the lower bits, which in turn reduces the complexity of decoders and encoders. The hardware architecture generated by hardware IP block synthesis system 100, once the unary computations are performed and converted to the binary format, may concatenate the output of each gi(x) with the separated upper bits. At the final stage, processing circuitry 120 may use the upper bits of the binary input to multiplex the expected final values among the results provided by each unary core.

The HBU techniques of this disclosure may have advantages when compared to other techniques. For example, the HBU techniques of sub-function similarity 180 may force an equal input range for all sub-functions, thereby allowing the derivation many sub-functions from a core set of sub-functions based on bit transformation. In contrast, standard HBU breaks an input function into sub-functions with limited input and output ranges and implements them based on the pure unary (PU) method, but does not limit the input ranges to equal ranges. Allowing unequal input ranges may result in a complex process that uses many parameters and considers sub-functions slopes and output ranges to break a function hierarchically.

Instead of a simple, pair-wise comparison of sub-functions sub-function similarity 180 uses optimization using similarity matrices and similarity vectors, e.g., the optimization listed above in the example pseudo-code for sub-function similarity 180 to find the subset of primary sub-functions and transformations to secondary sub-functions to implement the received function F(x). sub-function similarity 180 may also provide HBU with a trade-off between accuracy (in terms of maximum error) and hardware cost (in terms of area x delay).

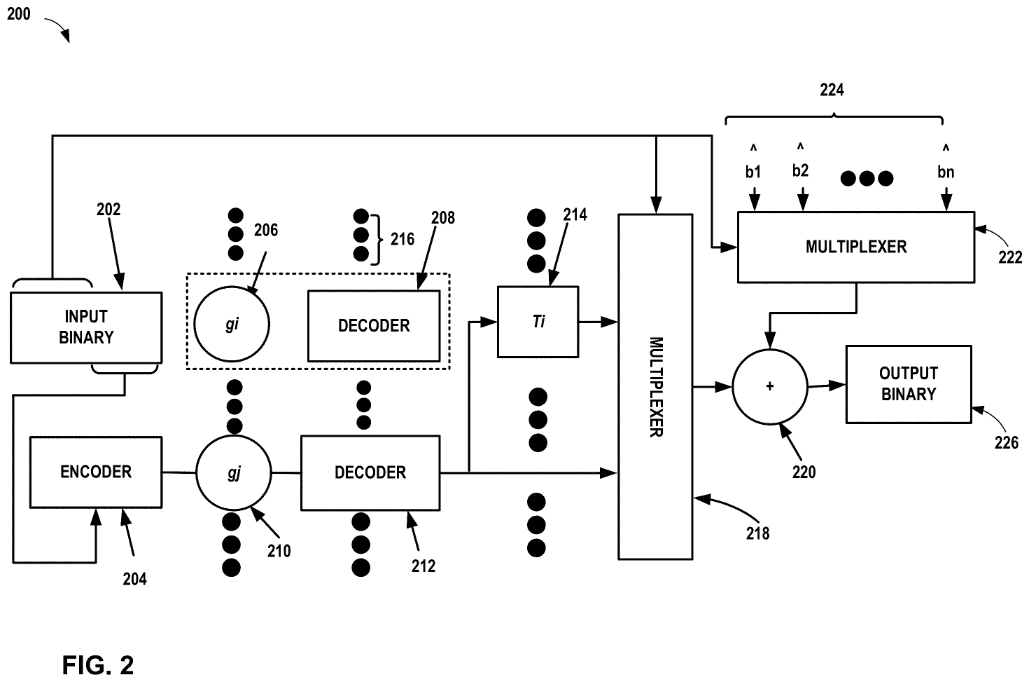

FIG. 2 is a block diagram illustrating an example hardware architecture of a function generated by sub-function similarity. Function 200 may be the hardware implementation of any received arbitrary function, e.g., F(x) as generated by hardware IP block synthesis system 100 described above in relation to FIG. 1. In some examples, function 200 may be implemented as circuitry, for example, as part of an integrated circuit. In the example of FIG. 2, function 200 includes an input binary 202, a single encoder 204, one or more primary sub-functions gⱼ206, implemented as pure unary cores, a respective decoder 208 for each primary sub-function, transformer Tᵢ214, multiplexor 218, multiplexor 222, summation node 220 and output binary 226. Function 200 may receive input binary 202 via an input circuit of function 200. In an example, an input circuit is configuration to receive an input for function 200.

As shown in the example of FIG. 2, gᵢ(x) 206 is derived from gⱼ(x) 210 through the transformer Tᵢ 214. Therefore, gᵢ(x) 206 is a secondary sub-function and gⱼ(x) 210 is a primary sub-function. In the example of FIG. 2, gⱼ 210 is equivalent to gⱼ(x) 210 and gᵢ 206 is equivalent to gᵢ(x) 206. When generating the hardware implementation of function 200, processing circuitry 120 of FIG. 1, may replace unary core gᵢ(x) 206 and its decoder 208 with a transformer, listed in Ti 214, that may include any of a variety of bit transformations such as NOT gates and/or shifters. This use of transformer Ti 214 may also reduce the fan-out of the input encoder. Such replacements make the hardware architecture of function 200 less expensive, e.g., compared to standard HBU described above in relation to FIG. 1, especially at higher resolutions. In some examples, function 200 may include first circuitry configured to implement operations of a primary sub-function (e.g., primary sub-function g(x) 210) to generate a first output based on lower bits of the input, the primary sub-function representing a first sub-function of function 200.

Although only one primary sub-function g(x) 210 is shown in the example of function 200, in other examples, function 200 may have any two or more primary sub-functions. As described above in relation to FIG. 1, processing circuitry 120 executes programming instructions in sub-function similarity 180 to determine a subset of primary sub-functions that would be implemented as a PU core, such as g(x) 210. The fewer primary sub-functions, then the fewer PU cores and therefore reduced area consumption for function 200 as implemented on the output computing device, e.g., computing device 110 described above in relation to FIG. 1. In operation, multiplexor 218 combines the one or more primary sub-functions gⱼ(x) 210 with the one or more secondary sub-functions output by transformer Tᵢ 214. Multiplexor 222 adds the respective biases 224 to each sub-function (primary and secondary), and combined with the output of multiplexor 218 by 220 to output binary 226. For instance, multiplexor 218 may be configured to select at least between the first output or the second output based on upper bits of the input to generate an output of the function for the input. Function 200 may use transformer Ti 214 to perform one or more operations. For example, transformer Ti 214 may be configured to perform operations of a secondary sub-function to generate a second output based on the first output, the secondary sub-function being derived from the primary sub-function based on a similarity between the secondary sub-function and the primary sub-function, and the second sub-function representing a second sub-function of the function. In some examples function 200 is configured to implement n-number of primary sub-functions that include the primary sub-function, where n is greater than or equal to 2. Function 200 may implement secondary sub-functions where each of the m-number of secondary sub-functions is derived from at least one of the n-number of primary sub-functions based on similarity between each of the m-number of secondary sub-functions and the at least one of the n-number of primary sub-functions.

As noted above, in some examples, function 200 may be implemented in circuitry, for example, as part of an integrated circuit. In some examples, the processing circuitry of function 200 may implement operations of a primary sub-function to generate a first output based on lower bits of the input, the primary sub-function representing a first sub-function of the function. Therefore, input binary 202 may be described as circuitry configured to receive a binary input. Output binary 226 may be described as circuitry configured to output the results of function 200 in the binary domain, e.g., the results computed by the primary and secondary sub-functions. As described above, function 200 includes a single binary-to-unary encoder 204 and one or more unary-to-binary decoders 212. Each decoder 212 receives the output of each respective primary sub-function, e.g., gⱼ 210, which is implemented as either a PU core, e.g., using wires and XOR gates, or as a look-up table and may be configured to decode unary output of the primary sub-function and the second sub-function into binary. In some examples, function 200 includes one or more binary-to-unary converters configured to convert the received binary input to unary input; and a unary-to-binary decoder configured to decode unary output of the primary sub-function into binary, where the function 200 receives the unary input and outputs to the unary-to-binary decoder

Function 200 further comprises transformer Tᵢ214, which may include circuitry such as NOT gates, shifters, and similar circuitry to derive secondary sub-functions from the primary sub-functions. Other circuitry included in function 200 includes multiplexor 218 and multiplexor 222 that adds the respective biases 224 to each sub-function. Multiplexor 218 may select at least between the first output or the second output based on upper bits of the input to generate an output of the function for the input. In some examples, multiplexor 218 is configured to select at least between the first output or one of the n-number of outputs based on upper bits of the input to generate the output of the function for the input. Multiplexor 222 may be configured to select biases to add to th results outputted by multiplexor 218, where the biases are selected based on at least one of the primary sub-function(s) and/or secondary sub-function(s). In some examples, function 200 may include second circuitry (e.g., multiplexor 222) concatenate the results outputted by the multiplexor with at least a first bias and a second bias, where the first bias is associated with the primary sub-function and the second bias is associated with the secondary sub-function.

In some examples, transformer 214 is configured to perform operations of a secondary sub-function to generate a second output based on the first output, the secondary sub-function being derived from the primary sub-function based on a similarity between the secondary sub-function and the primary sub-function, and the second sub-function representing a second sub-function of the function. Transformer 214 may perform operations of n-number of secondary subfunctions, where n is greater than or equal to 2. For instance, transformer 214 may be configured to perform operations of m-number of secondary sub-functions that include the secondary sub-function, where m is greater than or equal to 2. In some examples, transformer 214 is a first transformer, and function 200 includes n-number of transformers, where each of the n-number of transformers is configured to perform operations of a respective one of n-number of secondary sub-functions to generate n-number of outputs, where n is greater than or equal to 2.

Function 200 may use binary-to-unary encoder 204 and one or more unary-to-binary decoders 212 to convert between binary and unary. Binary-to-unary encoder 204 may be configured to convert a received binary input 202 to unary input. Unary-to-binary decoders 212 may be configured to decode unary output of the primary sub-function into binary, where the first circuitry (e.g., primary sub-function gj(x) 210) receives the unary input and outputs to the unary-to-binary decoder.

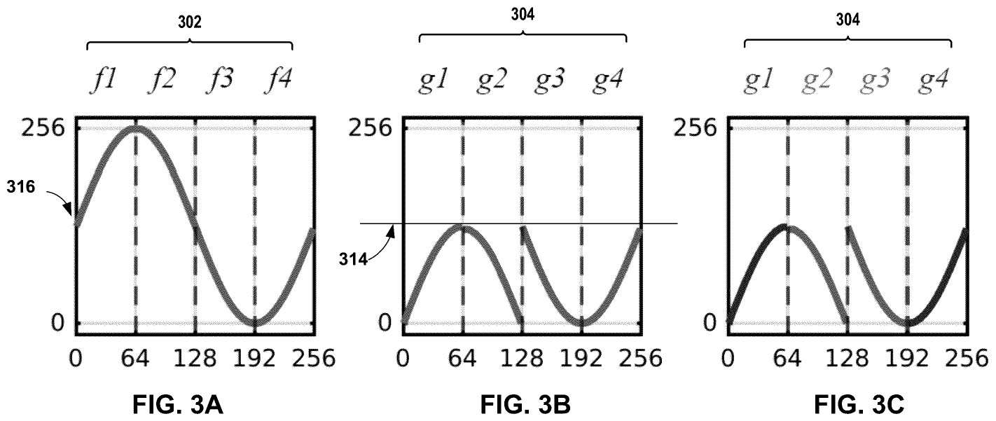

FIGS. 3A, 3B and 3C are graphs illustrating an example of breaking an input function into sub-functions according to one or more techniques of this disclosure. FIG. 3A shows an arbitrary w-bit function F(x)=[1+sin(2πx)]÷2. In the example of FIGS. 3A-3C, to process F(x), the digital system uses the parameters listed below:

Parameters

w = 8 bits
b = 2 bits
u = w − b = 6 bits
TargetErr = 2⁻⁷

The processing circuitry of this disclosure, e.g., processing circuitry 120 described above in relation to FIG. 1, may divide the function F(x) into 2^{b}=4 sub-functions 302 and separate the initial biases for each sub-function, as shown in FIGS. 3A and 3B, respectively. In the table below, the bias value for f1(x) is b1=128 and the bias value for f2(x) is b2=131. The bias values for f3(x) and f4(x) are b3=b4=0.

$$\begin{matrix}f 1 ( x ) = 128 + g 1 ( x ) & x ∈ [ 0 , 64 ) \\ f 2 ( x ) = 131 + g 2 ( x ) & x ∈ [ 64 , 126 ) \\ f 3 ( x ) = 0 + g 3 ( x ) & x ∈ [ 126 , 192 ) \\ f 4 ( x ) = 0 + g 4 ( x ) & x ∈ [ 192 , 256 )\end{matrix}$$

The processing circuitry may make pair-wise comparisons to find all the sub-functions, g1-g4 (304) that can be derived from each other, as described above in relation to FIGS. 1 and 2. The sub-functions 304 may have a uniform input range 314. In this disclosure, the term “generate” may be used as the inverse of deriving a function. In other words, if gᵢ can be derived from gⱼ through linear transformations, then gⱼ generates gᵢ.

Based on the target error equation described above in relation to FIG. 1, (∃T, Err(gᵢ, Tᵢ, gⱼ)≤TargetErr), the processing circuitry determines g₁(x) can generate g₃(x), g₃(x) can generate g₁(x), and g₄(x) can generate g₂(x).

$$\begin{matrix}T3 = inv ⇒ Err ( g 3 , inv , g 1 ) = 0.0038 \leq 2 - 7 , bm 3 = 1 \\ T 1 = inv ⇒ Err ( g 1 , inv , g 3 ) = 0.0058 \leq 2 - 7 , bm 1 = - 128 \\ T 2 = inv ⇒ Err ( g 2 , inv , g 4 ) = 0.0058 \leq 2 - 7 , bm 2 = - 3\end{matrix}$$

Although g4(x) can generate g2(x) through an inverter, the opposite may not be true. Due to the constraints on bm4, as described above, there is no transformation T4 such that Err(g₄, T₄, g₂)≤TargetError=2⁻⁷. For this reason, similarity matrices are not necessarily symmetric.

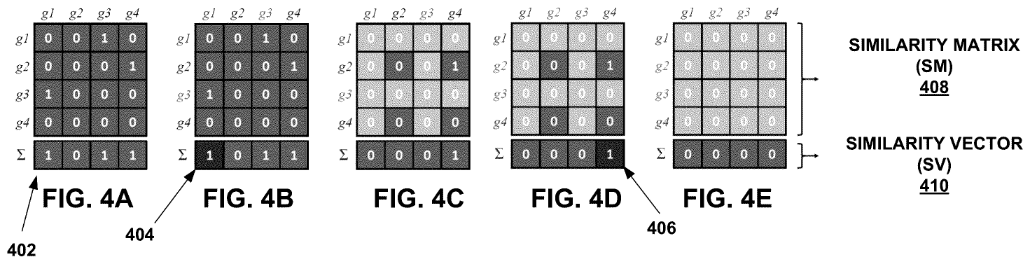

FIGS. 4A, 4B, 4C, 4D and 4E are example similarity matrices and similarity vectors for processing the example input function, F(x), described by FIGS. 3A-3C. FIGS. 4A-4E show a series similarity matrices 408 and similarity vectors 410 that illustrate the steps of the sub-function similarity process 180, described above in relation to FIG. 1.

After finding the derivable sub-functions, the processing circuitry computes the similarity matrix SM and similarity vector SV, as shown in FIG. 4A. The index of the maximum entry in SV determines the first unique sub-function. In present example, the first, the third, and the fourth entries in the similarity vector 402 are the same, and choosing either one would be OK. As shown in FIG. 4B, the processing circuitry selects f₁(x) as the first unique sub-function 404. Then, traversing through the 1st column of SM results in SM[3][1]=1. As a result:

$$\begin{matrix}SM [ 3 ] [ 1 ] = 1 ⇒ Err ( g 3 , inv , g 1 ) = 0.0038 \leq 2 - 7 \\ ⇒ ( 0 + g 3 ( x ) ) ≃ ( 0 + 1 ) + inv \{ g 1 ( x ) \} \\ ⇒ f 3 ( x ) ≃ 1 + inv \{ g 1 ( x ) \}\end{matrix}$$

Therefore, the processing circuitry may implement f3(x)≅1+inv{g1(x)} instead of f3(x)=0+g3(x).

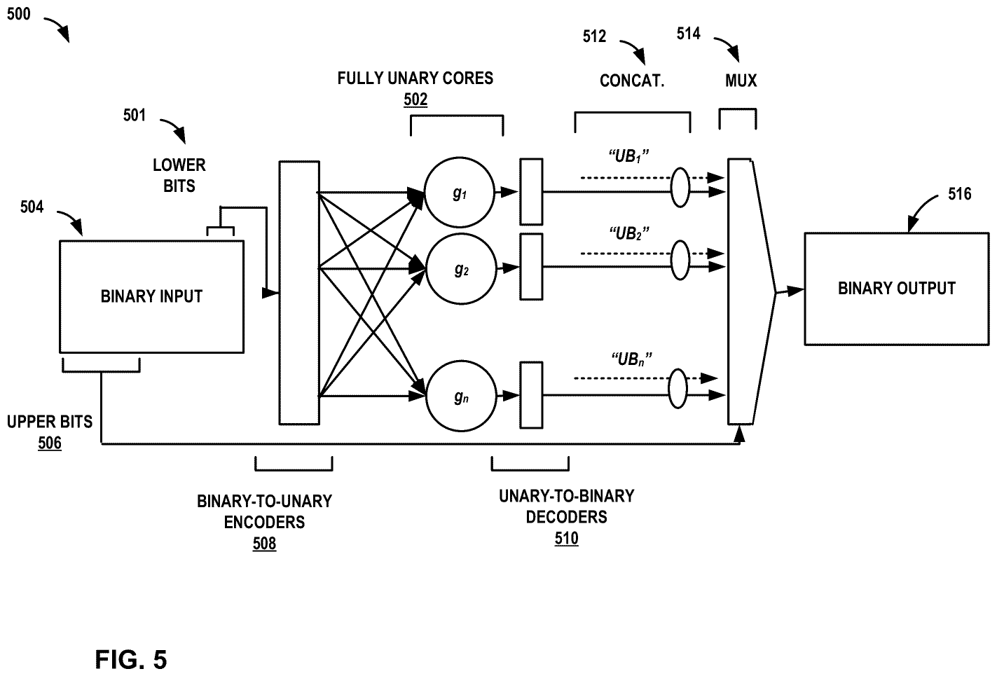

The processing circuitry may again update SM by zeroing the 1st and the 3rd rows and columns, and then recalculate SV, as shown in FIG. 4C. Again, FIG. 5D indicates that g4(x) is the next unique sub-function to be implemented. Similarly, the processing circuitry traverses through the 1st column, which results in SM[2][4]=1. As a result:

$$\begin{matrix}SM [ 2 ] [ 4 ] = 1 ⇒ Err ( g 2 , inv , g 1 ) = 0.0058 \leq 2 - 7 \\ ⇒ ( 131 + g 2 ( x ) ) ≃ ( 131 - 3 ) + inv \{ g 4 ( x ) \} \\ ⇒ f 2 ( x ) ≃ 128 + inv \{ g 4 ( x ) \}\end{matrix}$$

Therefore, the processing circuitry converts f2(x)=131+g2(x) to f2(x) 128+inv{g4(x)}. As a reminder, the bias value b2=131, shown above, and the value bm2=−3 was the bmi from the transformation deriving g2(x) from g4(x) shown above. As shown in FIG. 5E, zeroing the 4th and 2nd rows and columns sets all the entries of SM to zero and ends the process.

As a result of processing input function F(x), the processing circuitry divides the input function into four sub-functions F(x)≅\hat{f}(x):

$$\begin{matrix}\hat{f} 1 ( x ) = 128 + g 1 ( x ) & x ∈ [ 0 , 64 ) \\ \hat{f} 2 ( x ) = 128 + inv \{ g 4 ( x ) \} & x ∈ [ 64 , 126 ) \\ \hat{f} 3 ( x ) = 1 + inv \{ g 1 ( x ) \} & x ∈ [ 126 , 192 ) \\ \hat{f} 4 ( x ) = 0 + g 4 ( x ) & x ∈ [ 192 , 256 )\end{matrix}$$

In the example of FIGS. 3A-3C and 4A-4E, by executing t e instructions for the sub-function similarity process, the processing circuitry reduces the number of primary sub-functions (including the respective scaling networks and decoders) reduces by half. The secondary sub-functions are derived by bit transformations of the primary sub-functions, which may be stored in Tᵢ 214, described above in relation to FIG. 2. In the present example the bit transformations are simple NOT gates. FIG. 4C shows that g1(x) and f4(x) are the unique primary sub-functions and g2(x) and f3(x) are secondary sub-functions derived from the primary sub-functions.

FIG. 5 is a block diagram illustrating an example hardware architecture of a function generated by the function division and concatenation process. Function 500 may be the output hardware architecture of an input function, e.g., F(x) after processing circuitry 120, described above in relation to FIG. 1 executes the programming instructions for function concatenation 190. In the example of FIG. 5, function 500 includes binary input 504 from which upper bits 506 are temporarily separated from the set of sub-functions fᵢ (x) whose upper K bits 506 are fixed. Function 500 includes each truncated sub-function (denoted as gi(x)) implemented in the fully unary domain using only lower bits 501, shown in the example of FIG. 5 as fully unary cores 502. Binary-to-unary encoders 508 receive lower bits 501 and provide input to fully unary cores 502. Unary-to-binary decoders 510 receive the output of fully unary cores 502, e.g., g1(x)−gn(x), once the unary computations are performed and convert the output to binary format. The hardware then concatenates (512) the output of each gi(x) with the respective separated upper bits, UB₁−UBₙ. At the final stage, processing circuitry 120 may use the upper bits of the binary input to multiplex 514 the expected final values among the results provided by each unary core 502 as binary output 516.

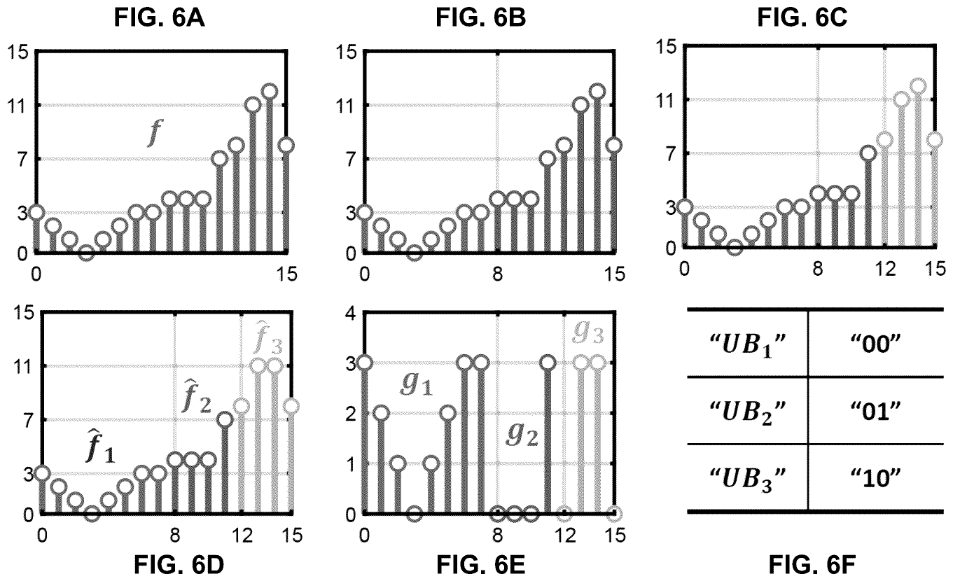

FIGS. 6A-6F are graphs illustrating an example of breaking an input function into sub-functions according to the function division and concatenation techniques of this disclosure. FIG. 6A shows an arbitrary function F(x) with wᵢₙ=4 bits and wₒᵤₜ=4 bits. In the present example, other parameters include: IL=3 bits, Lmin=2 bits, K=2 bits, TRE=2.5×10−2, and TSE=0.5×10−2.

Because wᵢₙ=4, and IL=3, the processing circuitry of this disclosure executing the programming instructions for function division and concatenation will initially divide the input domain ([0 15]) into two equal-sized sub-regions ([0, 7], and [8, 15]) and store the two sub-regions in the list f Boundaries as shown in FIG. 6B and described above in relation to FIG. 1. In the first iteration of the while loop, described above in relation to FIG. 1, the processing circuitry selects the first item from f Boundaries (i.e., [0, 7]) and removes the sub-region from the list. In this sub-region, the output values fsub=f ([0, 7]) ranges from 0 to 3, hence the upper K=2 bits are fixed. As a result, the processing circuitry stores this sub-region into gBoundaries and fsub values into \hat{f}.

In the next iteration, the processing circuitry selects the next item from f Boundaries ([8, 15]), shown in FIG. 6B, and remove this sub-region from the list. In this sub-region, fsub=f ([0, 7])={4, 4, 4, 7, 8, 11, 12, 8}, therefore, the upper 2 bits are not fixed. There are 2K=4 options for the upper bits' format, which are ‘00’, ‘01’, ‘10’, and ‘11’. The processing circuitry, executing the programming instructions to consider all the options separately and round the values to the nearest values whose upper 2 bits are the same. To illustrate some possible options for rounding the upper bits:

$$( 1 ) ’ 00 XX ’ ( i = 0 ) : ftemp = \{ 3 , 3 , 3 , 3 , 3 , 3 , 3 , 3 \}$$

$$( 2 ) ’ 01 XX ’ ( i = 1 ) : ftemp = \{ 4 , 4 , 4 , 7 , 7 , 7 , 7 , 7 \}$$

$$( 3 ) ’ 10 XX ’ ( i = 2 ) : ftemp = \{ 8 , 8 , 8 , 8 , 8 , 11 , 11 , 8 \}$$

$$( 4 ) ’ 11 XX ’ ( i = 2 ) : ftemp = \{ 12 , 12 , 12 , 12 , 12 , 12 , 12 , 12 \}$$

Among all these options, ‘01XX’ results in the best (lowest) rounding error, which is 8.59×10−2. However, because the error is not less than TRE (8.59×10−2>2.5×10−2), and the sub-region length has not reached the minimum allowable length Lmin (3≠2), the processing circuitry may not apply the approximation for this sub-region. Instead, the processing circuitry may divide the sub-region by 2 ([8, 11] and [12, 15]) and add each sub-region into f Boundaries, shown in FIG. 6C. At this time, f Boundaries still has 2 elements, and the processing circuitry goes through the while loop again.

In the next iteration, fsub=f ([8, 11]) ranges from 4 to 7, which means the upper 2 bits are fixed and the processing circuitry adds this sub-region to gBoundaries. As described above in relation to FIG. 1, gBoundaries is a list of sub-regions that are finalized. Processing circuitry may then add the transformed output of this sub-region into \hat{f}.

In the next iteration, fsub=f([12, 15]) ranges from 8 to 12, which means the upper 2 bits are not fixed. Similar to above, processing circuitry may again consider all four possible options and pick the best option which minimizes the rounding error. In the present example, the best option is to fix the upper bits as ‘10’ which results in the rounding error 1.56×10−2. Because the error is less than TRE, the processing circuitry may keep the changes and add this sub-function into \hat{f} and gBoundaries.

At this point, there is no region left in the queue (f Boundaries), and the while loop ends. At the last stage, processing circuitry 120 stores the upper K bits and the remaining lower bits of \hat{f} into g and UB, respectively. As a result of this algorithm, the processing circuitry divided the original function into three different sub-functions, shown in FIG. 6D, in which the upper two bits are fixed, and they can be safely truncated before performing the computations in the unary domain. FIG. 6E shows the truncated sub-functions and FIG. 6F shows the corresponding upper bits as well as the intermediate steps of the algorithm.

Since the original function was divided into three sub-regions corresponding to x ∈[0, 7], [8, 11], and [12, 15], a hardware implementation may use 3-to-7, 2-to-3, and 2-to-3 thermometer encoders (determined by the x range of sub-functions), followed by three fully unary cores which implement the truncated sub-functions. These encoders, use the lower bits of binary input to feed the unary cores. Because the output of each truncated sub-function ranges from 0 to 3, each core is connected to a 3-to-2 thermometer decoder separately.

Next, the hardware implementation, e.g., generated by synthesis algorithm 150 described above in relation to FIG. 1, may concatenate each output with its corresponding eliminated upper bits. Finally, the upper bits of the binary input are used to multiplex the correct output result for that particular input.

In some examples, to further reduce the hardware cost, programming instructions executed by the processing circuitry may check the possibility of implementing similar truncated sub-functions as one unary core. The processing circuitry may compare all the truncated sub-functions with the same input lengths together. In present example, there are two regions with the same input length which correspond to x∈[8, 11], and x∈[12, 15]. The similarity error between these two is equal to 0.14 which is greater than TSE, and hence these two regions are not similar enough to be implemented interchangeably.

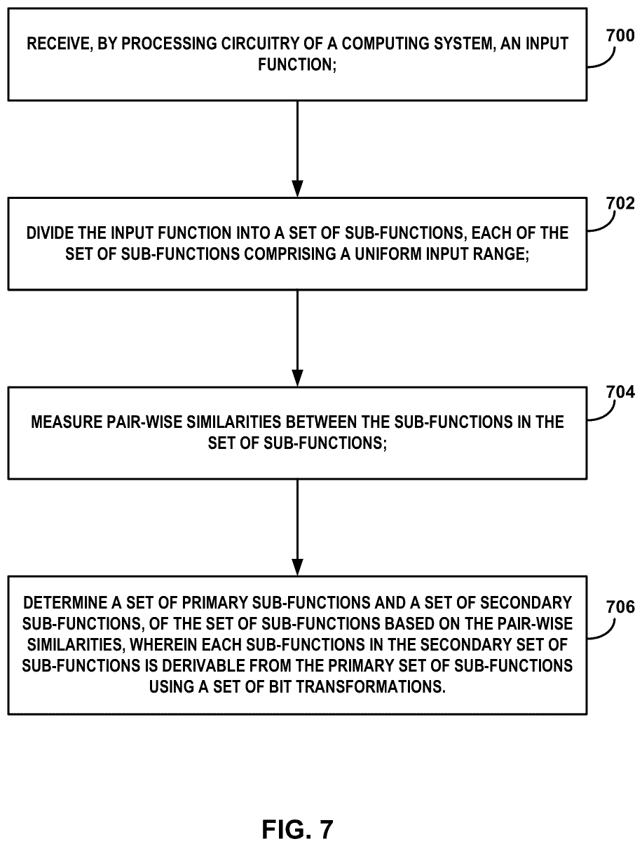

FIG. 7 is a flow chart illustrating an example operation based on the sub-function similarity techniques of this disclosure. The blocks of FIG. 7 will be described in terms of FIGS. 1 and 2, unless otherwise noted.

Processing circuitry 120 of hardware IP block synthesis system 100 may receive an input function (700), F(x), which may be any arbitrary input function, including a non-linear input function. Following programing instructions in sub-function similarity 180, processing circuitry 120 may divide input function F(x) into a set of sub-functions, each of the set of sub-functions comprising a uniform input range (702), e.g., uniform input range 314 described above in relation to FIG. 3B. Each sub-function may be a primary or a secondary sub-function.

Processing circuitry 120 may measure pair-wise similarities between the sub-functions in the set of sub-functions (704) to determine self-similarities between the sub-functions. Processing circuitry 120 may generate and iterate through similarity matrices and similarity vectors, described above in relation to FIGS. 1 and 4A-4E to determine a set of primary sub-functions and a set of secondary sub-functions, of the set of sub-functions based on the pair-wise similarities (706), in which each sub-functions in the secondary set of sub-functions is derivable from the primary set of sub-functions using a set of bit transformations.

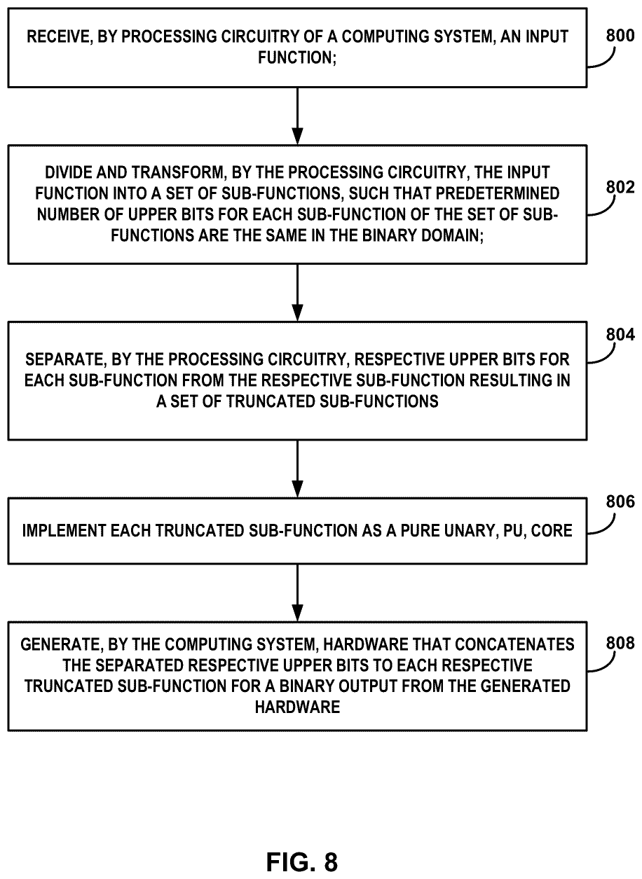

FIG. 8 is a flow chart illustrating an example operation based on the function division and concatenation techniques of this disclosure. The blocks of FIG. 8 will be described in terms of FIGS. 1 and 5, unless otherwise noted.

Following programming instructions in function concatenation 190, processing circuitry 120 of a hardware IP block synthesis system 100 may receive an input function F(x) (800). Processing circuitry 120 may divide and transform input function F(x) into a set of sub-functions, such that predetermined number of upper bits for each sub-function of the set of sub-functions are the same in the binary domain (802).

Processing circuitry 120 may separate respective upper bits for each sub-function from the respective sub-function (804) resulting in a set of truncated sub-functions, gᵢ(x) as shown in FIG. 5. Also as shown in FIG. 5, processing circuitry 120 of hardware IP block synthesis system 100 may implement each truncated sub-function as a fully unary core 502, shown in FIG. 5 (806). Processing circuitry 120 may generate hardware, e.g., MUX 514 of FIG. 5, that concatenates the separated respective upper bits 512 to each respective truncated sub-function for a binary output 516 from the generated hardware (808).

The techniques of this disclosure may also be described in the following examples.

Example 1. A method comprising: receiving, by processing circuitry of a computing system, an input function; dividing the input function into a set of sub-functions, each of the set of sub-functions comprising a uniform input range; measuring pair-wise similarities between the sub-functions in the set of sub-functions; and determining a set of primary sub-functions and a set of secondary sub-functions, of the set of sub-functions based on the pair-wise similarities, wherein: each sub-functions in the secondary set of sub-functions is derivable from the primary set of sub-functions using a set of bit transformations.

Example 2. The method of example 1, wherein the set of bit transformations comprises at least one of: an inversion, a right shift, or a left shift.

Example 3. The method of example 1, wherein measuring the pair-wise similarities comprises computing a similarity matrix, SM, and a similarity vector, SV.

Example 4. The method of example 3, wherein similarity vector, SV, is a vector of n elements and is equal to a summation of rows of the similarity matrix, SM, wherein the similarity vector, SV, is represented as:

$$SV = {[ {sv}_{j} ]}_{1 xn} ; {sv}_{j} = {\sum }_{i} {sm}_{ij} .$$

Example 5. The method of example 1, wherein there is an approximation error to derive a respective secondary sub-function from a respective primary sub-function is less than a threshold error.

Example 6. The method of example 5, further comprising, if there exists more than one bit transformations of the set of bit transformations to derive the respective secondary sub-function from the primary sub-function, choosing, by the processing circuitry, a bit transformation of the more than one bit transformations one that minimizes the approximation error.

Example 7. The method of example 1, further comprising, generating, by the computing system, a hardware implementation of the received function based on hybrid binary-unary (HBU) techniques.

Example 8. The method of example 7, wherein the hardware implementation comprises a single binary-to-unary encoder.

Example 9. The method of example 7, wherein the hardware implementation comprises a transformer, Ti, configured to store the set of bit transformations.

Example 10. A method comprising: receiving, by processing circuitry of a computing system, an input function; dividing and transforming, by the processing circuitry, the input function into a set of sub-functions, such that predetermined number of upper bits for each sub-function of the set of sub-functions are the same in the binary domain; separating, by the processing circuitry, respective upper bits for each sub-function from the respective sub-function resulting in a set of truncated sub-functions; generating, by the computing system, hardware that concatenates the separated respective upper bits to each respective truncated sub-function for a binary output from the generated hardware.

Example 11. The method of example 10, wherein concatenating the separated respective upper bits, comprises multiplexing the respective separated upper bits of the respective truncated sub-function for the binary output from the generated hardware.

Example 12. The method of example 10, wherein dividing and transforming the input function into a set of sub-functions comprises dividing the input length of input function into sub-regions.

Example 13. The method of example 10, wherein dividing and transforming the input function such that predetermined number of upper bits for each sub-function are the same in the binary domain comprises determining whether the predetermined number of upper bits is fixed.

Example 14. The method of example 13, further comprising, based on determining that the predetermined number of upper bits is not fixed for a respective sub-function of the set of sub-functions, rounding an output of respective sub-function to nearest values whose predetermined number of upper bits is fixed.

Example 15. The method of example 10, further comprising, reducing number of truncated sub-functions based on self-similarity techniques, wherein self-similarity techniques comprise measuring pair-wise similarities between the truncated sub-functions in the set of truncated sub-functions.

Example 16. A non-transitory computer-readable storage medium comprising instructions that, when executed, cause processing circuitry of a computing device to: receive an input function; divide the input function into a set of sub-functions, each of the set of sub-functions comprising a uniform input range; measure pair-wise similarities between the sub-functions in the set of sub-functions; determine a set of primary sub-functions and a set of secondary sub-functions, of the set of sub-functions based on the pair-wise similarities, wherein: each sub-functions in the secondary set of sub-functions is derivable from the primary set of sub-functions using a set of bit transformations.

Example 17. The non-transitory computer-readable storage medium of example 16 further comprising instructions that, when executed, cause processing circuitry of a computing device to perform the method of any of examples 2-9.

Example 18. A non-transitory computer-readable storage medium comprising instructions that, when executed, cause processing circuitry of a computing device to: receive an input function; divide and transform the input function into a set of sub-functions, such that predetermined number of upper bits for each sub-function of the set of sub-functions are the same in the binary domain; separate respective upper bits for each sub-function from the respective sub-function resulting in a set of truncated sub-functions; generate hardware that concatenates the separated respective upper bits to each respective truncated sub-function for a binary output from the generated hardware.

Example 19. The non-transitory computer-readable storage medium of example 18 further comprising instructions that, when executed, cause processing circuitry of a computing device to perform the method of any of examples 10-15.

Example 20. A circuit comprising: circuitry configured to receive a binary input; a single binary-to-unary encoder configured to convert the received binary input to unary input; one or more implemented primary sub-functions configured to receive the converted unary input; one or more unary-to-binary decoders, wherein each respective unary-to-binary decoders is configured to receive a respective output from a respective primary sub-function of the one or more primary sub-functions; a transformer, wherein the transformer comprises circuitry configured to derive secondary sub-functions from the primary sub-functions; circuitry configured to output results computed by the primary sub-functions and the secondary sub-functions.

Example 21. The circuit of claim 20, further comprising one or more pure unary, PU, cores, configured to receive the converted unary input wherein each PU core is configured to implement a primary sub-function.

In one or more examples, the functions described above may be implemented in hardware, software, firmware, or any combination thereof. For example, the various components of FIG. 1 such as hardware IP block synthesis system 100, processing circuitry 120, and computing device 110 may be implemented in hardware, software, firmware, or any combination thereof. If implemented in software, the functions may be stored on or transmitted over, as one or more instructions or code, a computer-readable medium and executed by a hardware-based processing unit. Computer-readable media may include computer-readable storage media, which corresponds to a tangible medium such as data storage media, or communication media including any medium that facilitates transfer of a computer program from one place to another, e.g., according to a communication protocol. In this manner, computer-readable media generally may correspond to (1) tangible computer-readable storage media which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable medium.

The term “non-transitory” may indicate that the storage medium is not embodied in a carrier wave or a propagated signal. In certain examples, a non-transitory storage medium may store data that can, over time, change (e.g., in RAM or cache). By way of example, and not limitation, such computer-readable storage media, may include random access memory (RAM), read only memory (ROM), programmable read only memory (PROM), erasable programmable read only memory (EPROM), electronically erasable programmable read only memory (EEPROM), flash memory, a hard disk, a compact disc ROM (CD-ROM), a floppy disk, a cassette, magnetic media, optical media, or other computer readable media. In some examples, an article of manufacture may include one or more computer-readable storage media.

Also, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transient media, but are instead directed to non-transient, tangible storage media. Combinations of the above should also be included within the scope of computer-readable media.

Instructions may be executed by one or more processors, such as one or more DSPs, general purpose microprocessors, ASICs, FPGAs, or other equivalent integrated or discrete logic circuitry. Accordingly, the term “processor” and “processing circuitry,” as used herein, may refer to any of the foregoing structure or any other structure suitable for implementation of the techniques described herein. Also, the techniques could be fully implemented in one or more circuits or logic elements.

The techniques of this disclosure may be implemented in a wide variety of devices or apparatuses, including, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a hardware unit or provided by a collection of interoperative hardware units, including one or more processors as described above, in conjunction with suitable software and/or firmware.

Various examples of the disclosure have been described. These and other examples are within the scope of the following claims.

What is claimed is:

1. A circuit to implement a function, the circuit comprising:
an input circuit configured to receive an input for the function;
first circuitry configured to implement operations of a primary sub-function to generate a first output based on lower bits of the input, the primary sub-function representing a first sub-function of the function;
a transformer configured to perform operations of a secondary sub-function to generate a second output based on the first output, the secondary sub-function being derived from the primary sub-function based on a similarity between the secondary sub-function and the primary sub-function, and the second sub-function representing a second sub-function of the function; and
a multiplexer configured to select at least between the first output or the second output based on upper bits of the input to generate an output of the function for the input.

2. The circuit of claim 1, wherein the first circuitry comprises one or more pure unary, PU, cores or lookup tables.

3. The circuit of claim 2, wherein the one or more PU cores are implemented using XOR gates.

4. The circuit of claim 1, wherein the input includes a binary input.

5. The circuit of claim 4, further comprising:
one or more binary-to-unary converters configured to convert the received binary input to unary input; and
a unary-to-binary decoder configured to decode unary output of the primary sub-function into binary,
wherein the first circuitry receives the unary input and outputs to the unary-to-binary decoder.

6. The circuit of claim 1, wherein the first circuitry is further configured to implement n-number of primary sub-functions that include the primary sub-function, wherein n is greater than or equal to 2, and
wherein the transformer is further configured to perform operations of m-number of secondary sub-functions that include the secondary sub-function, wherein m is greater than or equal to 2.

7. The circuit of claim 6, wherein each of the m-number of secondary sub-functions is derived from at least one of the n-number of primary sub-functions based on similarity between each of the m-number of secondary sub-functions and the at least one of the n-number of primary sub-functions.

8. The circuit of claim 1, wherein the multiplexor is a first multiplexor, and further comprising a second multiplexor configured to select biases to add to the results outputted by the first multiplexor, wherein the biases are selected based on at least one of the primary sub-function or the secondary sub-function.

9. The circuit of claim 1, wherein the circuit further comprises second circuitry configured to concatenate the results outputted by the multiplexor with at least a first bias and a second bias, wherein the first bias is associated with the primary sub-function and the second bias is associated with the secondary sub-function.

10. The circuit of claim 1, wherein the transformer is a first transformer, and wherein the circuit further comprises n-number of transformers, wherein each of the n-number of transformers is configured to perform operations of a respective one of n-number of secondary sub-functions to generate n-number of outputs, where n is greater than or equal to 2.

11. The circuitry of claim 10, wherein the multiplexer is configured to select at least between the first output or one of the n-number of outputs based on upper bits of the input to generate the output of the function for the input.

12. A method comprising:
receiving, by processing circuitry of a computing system, an input for a function;
implementing, by the processing circuitry, operations of a primary sub-function to generate a first output based on lower bits of the input, the primary sub-function representing a first sub-function of the function;
performing, by the processing circuitry, operations of a secondary sub-function to generate a second output based on the first output, the secondary sub-function being derived from the primary sub-function based on a similarity between the secondary sub-function and the primary sub-function, and the second sub-function representing a second sub-function of the function;
selecting, by the processing circuitry, at least between the first output or the second output based on upper bits of the input to generate an output of the function for the input.

13. The method of claim 12, wherein the processing circuitry comprises one or more pure unary, PU, cores or look-up tables.

14. The method of claim 13, wherein the one or more PU cores are implemented using XOR gates.

15. The method of claim 12, wherein the input includes binary input.

16. The method of claim 15, further comprising:
converting, by the processing circuitry, the received binary input to unary input via one or more binary-to-unary encoders; and
decoding, by the processing circuitry, unary output of the primary sub-function into binary via a unary-to-binary encoder.

17. The circuit of claim 1, further comprising:
implementing, by the processing circuitry n-number of primary sub-functions that include the primary sub-function, wherein n is greater than or equal to 2, and
performing, by the processing circuitry, operations of m-number of secondary sub-functions that include the secondary sub-function, wherein m is greater than or equal to 2.

18. The method of claim 17, wherein each of the m-number of secondary sub-functions is derived from at least one of the n-number of primary sub-functions based on similarity between each of the m-number of secondary sub-functions and the at least one of the n-number of primary sub-functions.

19. The method of claim 12, further comprising selecting, by the processing circuitry, biases to add to the results outputted by the multiplexor, wherein the biases are selected based on at least one of the primary sub-function or the secondary sub-function.

20. A method comprising:
receiving, by processing circuitry of a computing system, an input function;
dividing the input function into a set of sub-functions, each of the set of sub-functions comprising a uniform input range;
measuring pair-wise similarities between the sub-functions in the set of sub-functions; and
determining a set of primary sub-functions and a set of secondary sub-functions, of the set of sub-functions based on the pair-wise similarities, wherein:
each sub-functions in the secondary set of sub-functions is derivable from the primary set of sub-functions using a set of bit transformations.
